(19) United States
(12) Patent Application Publication
(10) Pub. No.: US 2011/0297981 A1
(43) Pub. Date: Dec. 8, 2011

(54) FLUORESCENT STRUCTURE AND METHOD FOR FORMING THE FLUORESCENT STRUCTURE AND LED PACKAGE USING THE SAME

(75) Inventors: CHI-WEI LIAO, Hsinchu (TW); WEN-LIANG TSENG, Hsinchu (TW); CHIH-YUNG LIN, Hsinchu (TW); MIN-TSUN HSIEH, Hsinchu (TW); CHING-LIEN YEH, Hsinchu (TW)

(73) Assignee: ADVANCED OPTOELECTRONIC TECHNOLOGY, INC., Hsinchu Hsien (TW)

(21) Appl. No.: 12/987,143

(22) Filed: Jan. 9, 2011

(30) Foreign Application Priority Data
Jun. 3, 2010 (CN) 201010191056.1

(51) Int. Cl. H01L 33/50; B32B 37/12; B32B 5/12; B32B 38/00; B32B 3/10; B32B 3/02

(52) U.S. Cl. 257/98; 428/203; 428/66.5; 428/105; 156/242; 156/182; 257/E33.061

(57) ABSTRACT

A fluorescent structure for a light-emitting package includes a first fluorescent layer and a second fluorescent layer covering the first fluorescent layer. The first fluorescent layer includes first fluorescent strips, and defines first transparent regions between the first fluorescent strips. The second fluorescent layer includes second fluorescent strips, and defines second transparent regions between the second fluorescent strips. A method for forming the fluorescent structure and a light-emitting diode package using the fluorescent structure are also provided.

### TECHNICAL FIELD

The present disclosure generally relates to a fluorescent structure and a method forming the same, and more particularly to a light-emitting diode (LED) package having the fluorescent structure.

### BACKGROUND

Light emitting diodes (LEDs) have the benefit of a small size and a great light efficiency. One of the related methods of manufacturing a white LED package is coating a blue chip with encapsulant and yellow fluorescent powder added therein. In such a case, the emitted light from the white LED package only has two wavelengths of blue light and yellow light. Another method of manufacturing the white LED package is to use the blue light of a blue LED chip to activate red fluorescent powder and green fluorescent powder. Accordingly, the emitted light has three wavelengths of blue light, red light and green light. However, it is hard to control usage of the fluorescent power, and an undesired distribution of the fluorescent powder causes a color deviation problem and poor light efficiency.

Therefore, it is desirable to provide a fluorescent structure, which can overcome the described limitations.

### BRIEF DESCRIPTION OF THE DRAWINGS

Many aspects of the LED packages can be better understood with reference to the following drawings. The components in the drawings are not necessarily drawn to scale, emphasis instead being placed upon clearly illustrating the principles of the present invention. Moreover, in the drawings, like reference numerals designate corresponding parts throughout the several views.

FIG. 1 is a top view of an LED package according to a first embodiment.

FIG. 2 is a cross section view of the LED package along the cross line II-II of FIG. 1.

FIG. 3 is a top view of an LED package according to a second embodiment.

FIG. 4 is a cross section view of the LED package along the cross line IV-IV of FIG. 3.

FIG. 5 is a top view of an LED package according to a third embodiment.

FIG. 6 is a cross section view of the LED package along the cross line VI-VI of FIG. 5.

FIG. 7 is a flowchart of a method of forming a fluorescent structure according to a fourth embodiment.

FIG. 8 is a flowchart of a method of forming a fluorescent structure according to a fifth embodiment.

### DETAILED DESCRIPTION

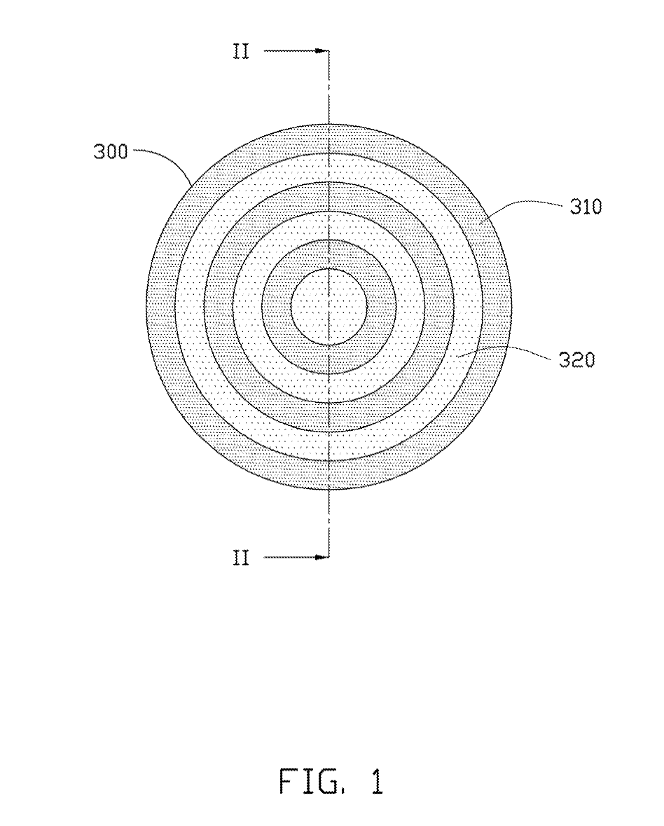

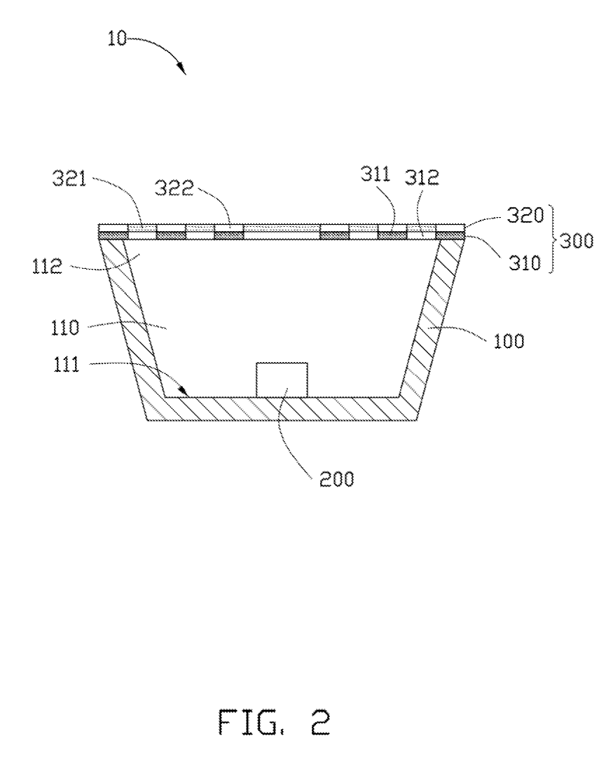

As shown in FIG. 1 and FIG. 2, an LED package 10 includes a cup base 100, an LED chip 200 located on the cup base 100 and a fluorescent structure 300 covering the LED chip 200.

The cup base 100 defines a recess 110, and the recess 110 has a bottom surface 111 and a top opening 112. The LED chip 200 is located on the bottom surface 111 of the recess 110, and emits light toward the top opening 112 of the recess 110. In this embodiment, the LED chip 200 may be a blue LED chip, but is not limited thereto.

The fluorescent structure 300 is located on the top opening 112 of the cup base 100. The fluorescent structure 300 is a flat plate including a first fluorescent layer 310 and a second fluorescent layer 320 covering the first fluorescent layer 310. The first fluorescent layer 310 includes first fluorescent strips 311, and defines first transparent regions 312 between the first fluorescent strips 311. Each first fluorescent strip 311 bends to form a ring around a center point, so the first fluorescent strips 311 are concentric rings spaced apart from each other. The distance between the adjacent first fluorescent strips 311 is substantially less than one millimeter.

The second fluorescent layer 320 includes second fluorescent strips 321, and defines second transparent regions 322 between the second fluorescent strips 321. Each second fluorescent strip 321 bends to form a ring around a center point, so the second fluorescent strips 321 are concentric rings spaced apart from each other. The distance between the adjacent second fluorescent strips 321 is substantially less than one millimeter.

In a top view of the stacked first fluorescent layer 310 and second fluorescent layer 320, the first fluorescent strips 311 and the second fluorescent strips 321 are staggered. The first fluorescent strips 311 correspond to the second transparent regions 322, and the second fluorescent strips 321 correspond to the first transparent regions 312. Since the distance between two adjacent first fluorescent strips 311, and the distance between two adjacent second fluorescent strips 321 each are less than one millimeter, the emitted light can be well mixed and the stripes are not observed by viewers. Thus, light from the fluorescent structure 300 appears to be uniform to observers. If the distance between fluorescent strips exceeds one millimeter, light from the fluorescent structure 300 may have stripe pattern to observers.

In this embodiment, the first fluorescent strips 311 and the second fluorescent strips 321 respectively include red fluorescent material and green fluorescent material therein, but are not limited thereto. For example, the first fluorescent strips 311 and the second fluorescent strips 321 may respectively include green fluorescent material and red fluorescent material in other embodiments. The red fluorescent material may be sulfide or nitride, such as Y₂O₂S:(Eu, Gd, Bi), (Sr, Ca)S:(Eu, Ce), SrY₂S₄:Eu, CaLa₂S:Ce or CaSiN₂:Ce. The green fluorescent material may be sulfide, nitride or silicate, such as (Sr, Ca, Ba)(Al, Ga)₂S:Eu, SrSi₂O₂N₂:Eu, SrS:(Eu, Ce), ZnS:(Cu, Al) or Ca₂MgSi₂O₇:Cl.

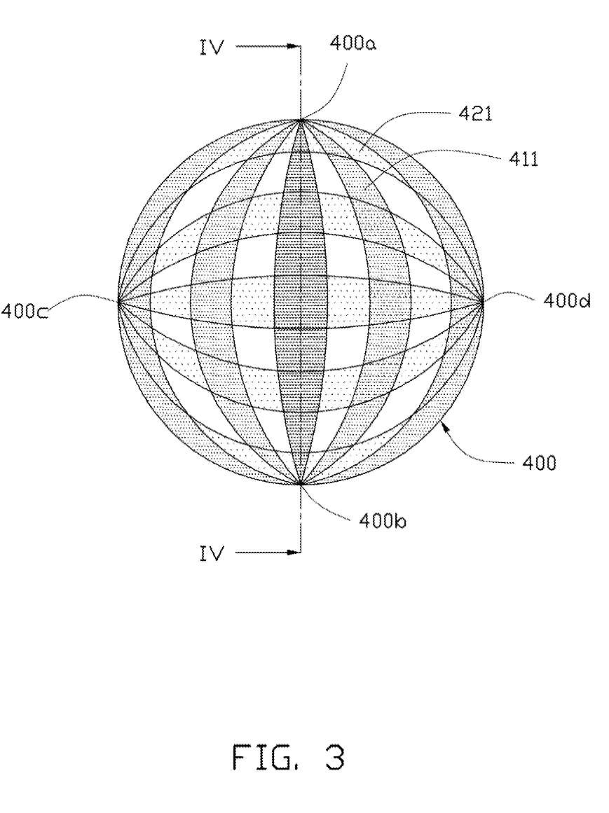

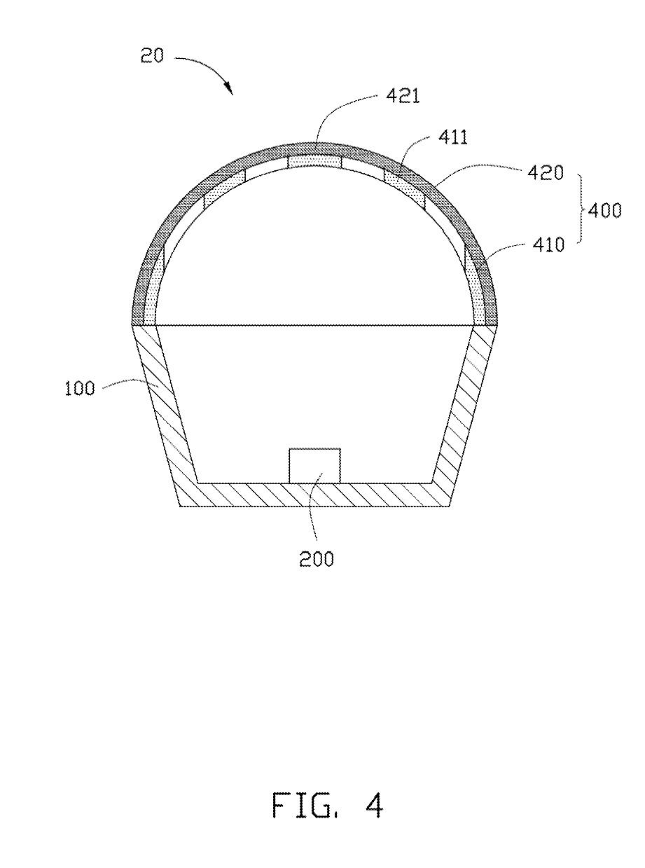

As shown in FIG. 3 and FIG. 4, a second embodiment differs from the first embodiment only in the shape and pattern of the fluorescent structure. The fluorescent structure 400 is a semi-spherical shell having a circular edge in the LED package 20, and includes a first fluorescent layer 410 and a second fluorescent layer 420 covering the first fluorescent layer 410. The fluorescent structure 400 defines a first point 400a, a second point 400b, a third point 400c and a fourth point 400d on the circular edge. A first extension line passing the first point 400a and the second point 400b is perpendicular to a second extension line passing the third point 400c and the fourth point 400d. For example, the first extension line and the second first extension line may be two different diameters of the circular edge.

The first fluorescent layer 410 consists of a plurality of first strips 411, neighboring two of which are spaced from each other by a first transparent region (not labeled). The second fluorescent layer consists of a plurality of second strips 421, neighboring two of which are spaced from each other by a second transparent region (not labeled). Each first fluorescent strip 411 and each second fluorescent strip 421, except a middle one, are both crescents in this embodiment. The middle first fluorescent strip 411 and the middle second fluorescent strip 421 each have a biconvex shape. Each first fluorescent strip 411 passes both the first point 400a and the second point 400b, and is separated from each other. Each second fluorescent strip 421 passes both the third point 400c and the fourth point 400d, and is separated from each other. In top view of the stacked first fluorescent layer 410 and second fluorescent layer 420, the first fluorescent strips 411 cross the second fluorescent strips 421 to form a mesh-like structure. The maximum distance between two adjacent first fluorescent strips 411, and the maximum distance between two second fluorescent strips 421 are less than one millimeter to avoid the strip light effect.

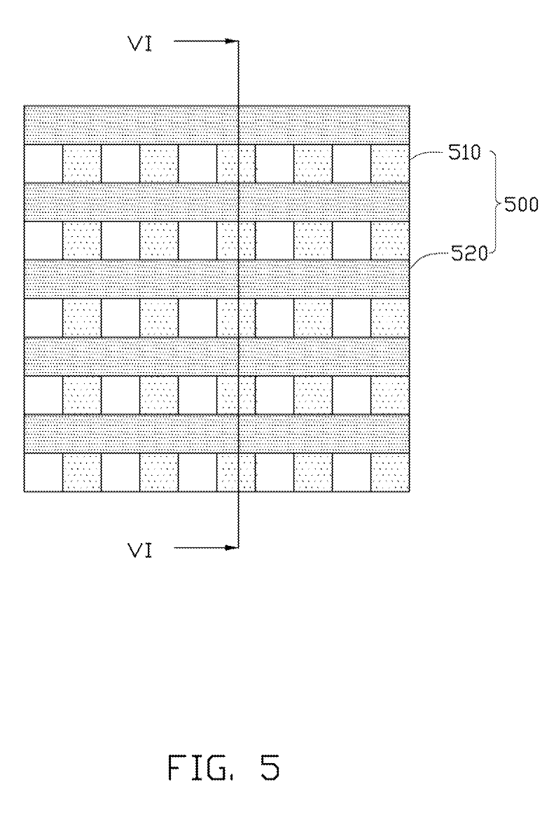

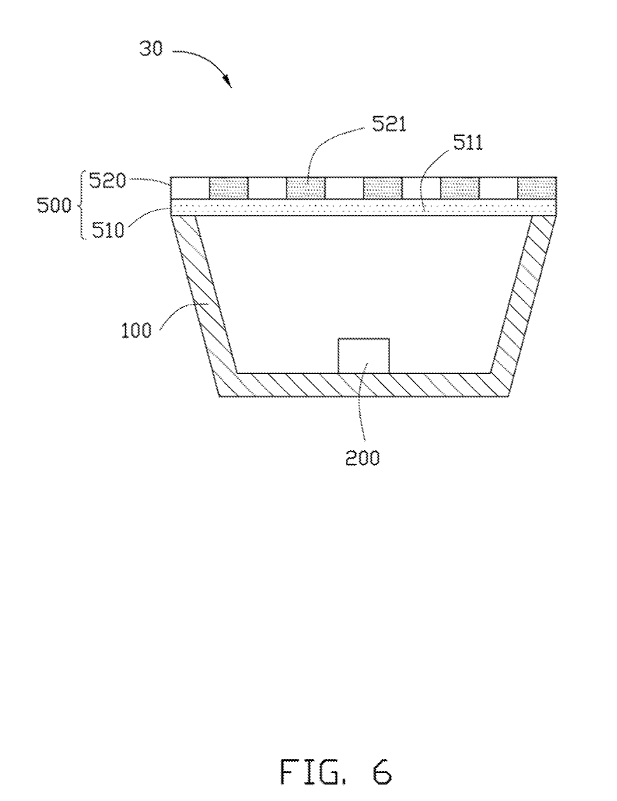

As shown in FIG. 5 and FIG. 6, a third embodiment differs from the first embodiment only in the pattern of the fluorescent structure. The fluorescent structure 500 is a flat plate including a first fluorescent layer 510 and a second fluorescent layer 520 covering the first fluorescent layer 510 in the LED package 30. Each first fluorescent strip 511 and each second fluorescent strip 521 are both rectangular. The first fluorescent strips 511 are parallel to each other, and separated from each other. The second fluorescent strips 521 are parallel and separated from each other.

In a top view of the stacked first fluorescent layer 510 and second fluorescent layer 520, the first fluorescent strips 511 crisscross the second fluorescent strips 521 to form a mesh pattern. The distance between two adjacent first fluorescent strips 511, and the distance between two second fluorescent strips 521 are less than one millimeter to avoid the checker light effect.

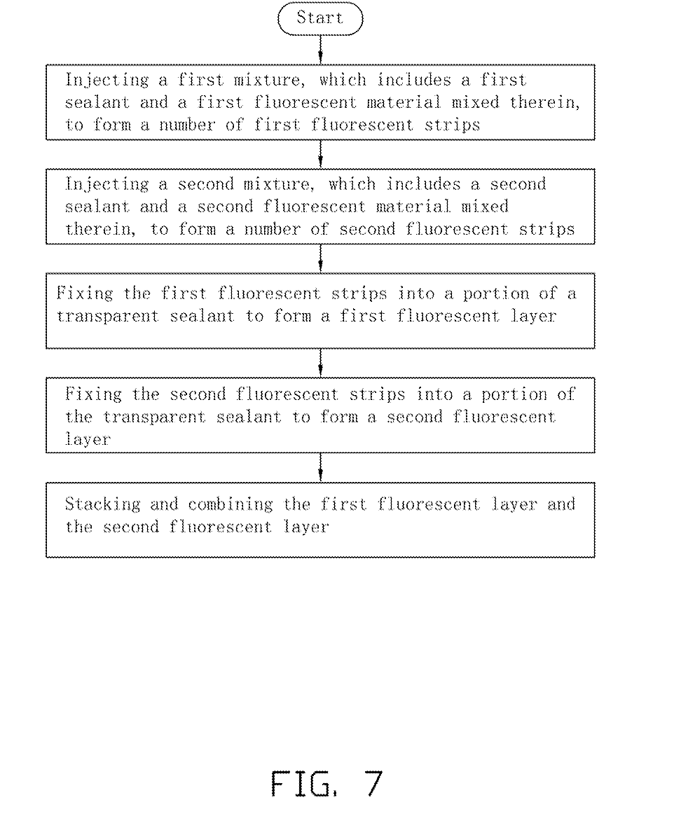

As shown in FIG. 7, a method of forming the fluorescent structure of the present disclosure includes the following steps. A first mixture, which comprises a first sealant and a first fluorescent material mixed therein, is injected to form first fluorescent strips. The first fluorescent strips may be injected into a mold designed in the required shape, such as the concentric rings of FIG. 1, the crescents and the middle biconvex middle one of FIG. 3 or the rectangular strips of FIG. 5. In other embodiments, the first fluorescent strips may be formed by injection molding into a fluorescent film, and then can be cut into the required shape. The formed first fluorescent strips are arranged into a design pattern, such as the concentric rings of FIG. 1, the symmetrical crescents about the middle biconvex one of FIG. 3 or the parallel lines of FIG. 5, and are fixed into a portion of a transparent sealant to form the first fluorescent layer. A maximum distance between the adjacent first fluorescent strips is less than one millimeter.

Similar as above, a second mixture, which comprises a second sealant and a second fluorescent material mixed therein, is injected to form second fluorescent strips. The second fluorescent strips may be injected into a mold designed in the required shape, such as the concentric rings of FIG. 1, the crescents and the middle biconvex one of FIG. 3 or the rectangular strips of FIG. 5, or may be formed by injection molding into a fluorescent film, and then can be cut into the required shape. The formed second fluorescent strips are arranged into a design pattern, such as the concentric rings of FIG. 1, the symmetrical crescents about the middle biconvex one of FIG. 3 or the parallel lines of FIG. 5, and are fixed into a portion of a transparent sealant to form the second fluorescent layer. A maximum distance between the adjacent second fluorescent strips is less than one millimeter.

The first fluorescent layer and the second fluorescent layer are stacked and combined to form the fluorescent structure. For example, the first fluorescent layer and the second fluorescent layer are combined by a hot pressing process or adhesive. It is noted that the performing order of the above steps may be adjusted. For example, the step of forming the second fluorescent strips may be performed before, after or simultaneously with the step of forming the first fluorescent strips.

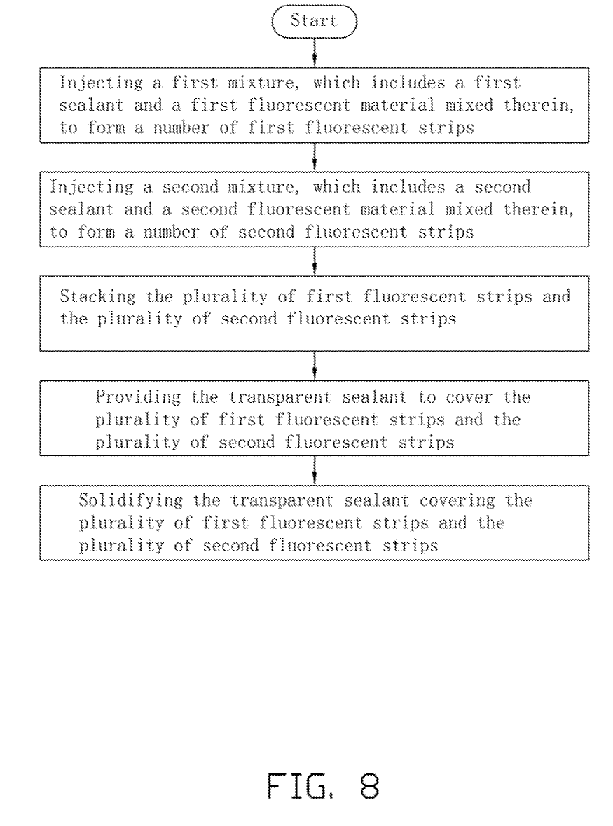

As shown in FIG. 8, another method of forming the fluorescent structure of the embodiment is provided. This method differs from the above method only in the step of fixing the first fluorescent strips and the second fluorescent strips. The first fluorescent strips and the second fluorescent strips are directly stacked together and arranged into the design pattern, so the concentric rings of FIG. 1, the crossed crescents and middle biconvex ones of FIG. 3 or the mesh of FIG. 5, and a transparent sealant is provided to directly cover the first fluorescent strips and the second fluorescent strips. Next, the transparent sealant covering the first fluorescent strips and the second fluorescent strips is solidified to form the fluorescent structure.

The fluorescent structure of the present disclosure includes the stacked first fluorescent layer and second fluorescent layer, and the first and second fluorescent layers include first and second fluorescent strips. Thus, the amount, densities and positions of the first fluorescent material and the second fluorescent material can be accurately controlled in the fluorescent structure. Accordingly, the uniformity of the fluorescent material can be easily adjusted to control the light-mixing result and brightness of the LED package.

It is believed that the present embodiment and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A fluorescent structure for a light emitting diode (LED) package, comprising:
a first fluorescent layer, the first fluorescent layer comprising a plurality of first fluorescent strips, the first fluorescent layer defining a plurality of first transparent regions between the plurality of first fluorescent strips; and
a second fluorescent layer covering the first fluorescent layer, the second fluorescent layer comprising a plurality of second fluorescent strips, and the second fluorescent layer defining a plurality of second transparent regions between the plurality of second fluorescent strips.

2. The fluorescent structure of claim 1, wherein a maximum distance between every two of the plurality of first fluorescent strips is less than one millimeter, and a maximum distance between every two of the plurality of second fluorescent strips is less than one millimeter.

3. The fluorescent structure of claim 1, wherein the plurality of first fluorescent strips are a plurality of first concentric rings apart from each other, and the plurality of second fluorescent strips are a plurality of second concentric rings apart from each other.

4. The fluorescent structure of claim 3, wherein the plurality of first concentric rings correspond to the plurality of second transparent regions, and the plurality of second concentric rings correspond to the plurality of first transparent regions.

5. The fluorescent structure of claim 4, wherein the fluorescent structure is a flat plate.

6. The fluorescent structure of claim 1, wherein the fluorescent structure is a semi-spherical shell having a circular edge, the semi-spherical shell defines a first point, a second point, a third point and a fourth point on the circular edge, the first point being opposite to the second point, and the third point being opposite to the fourth point.

7. The fluorescent structure of claim 6, wherein each of the plurality of first fluorescent strips passes both the first and the second points, and each of the plurality of second fluorescent strips passes both the third and the fourth points.

8. The fluorescent structure of claim 7, wherein a first extension line passing the first and the second points is perpendicular to a second extension line passing the third and the fourth points.

9. The fluorescent structure of claim 8, wherein at least some of the plurality of first fluorescent strips and the second fluorescent strips are crescents.

10. The fluorescent structure of claim 1, wherein the plurality of first fluorescent strips are a plurality of first rectangles paralleled to each other, and the plurality of second fluorescent strips are a plurality of second rectangles paralleled to each other.

11. The fluorescent structure of claim 10, wherein the plurality of first rectangles crisscross the plurality of second rectangles to form a meshed pattern.

12. The fluorescent structure of claim 11, wherein the fluorescent structure is a flat plate.

13. The fluorescent structure of claim 1, wherein the first fluorescent strips and the second fluorescent strips respectively comprise red fluorescent material and green fluorescent material.

14. The fluorescent structure of claim 13, wherein the red fluorescent material is selected from a group consisting of Y₂O₂S:(Eu, Gd, Bi), (Sr, Ca)S:(Eu, Ce), SrY₂S₄:Eu, CaLa₂S:Ce or CaSiN₂:Ce, and

15. The fluorescent structure of claim 13, wherein the green fluorescent material is selected from a group consisting of (Sr, Ca, Ba)(Al, Ga)₂S:Eu, SrSi₂O₂N₂:Eu, SrS:(Eu, Ce), ZnS:(Cu, Al) or Ca₂MgSi₂O₇:Cl.

16. A light emitting diode package, comprising:
a cup base;
a light emitting diode located in the cup base; and
a fluorescent structure located on the cup base and covering the light emitting diode,
the fluorescent structure comprising:
a first fluorescent layer, the first fluorescent layer comprising a plurality of first fluorescent strips, the first fluorescent layer defining a plurality of first transparent regions between the plurality of first fluorescent strips; and
a second fluorescent layer covering the first fluorescent layer, the second fluorescent layer comprising a plurality of second fluorescent strips, and the second fluorescent layer defining a plurality of second transparent regions between the plurality of second fluorescent strips, wherein a maximum distance between every two of the plurality of first fluorescent strips is less than one millimeter, and a maximum distance between every two of the plurality of second fluorescent strips is less than one millimeter.

17. The light emitting diode package of claim 16, wherein the cup base comprises a recess, the light emitting diode is located on a bottom of the recess, and the fluorescent structure is located over the recess of the cup base.

18. A method of forming a fluorescent structure for a light emitting diode (LED) package, comprising:
injecting a first mixture, which comprises a first sealant and a first fluorescent material mixed therein, to form a plurality of first fluorescent strips;
injecting a second mixture, which comprises a second sealant and a second fluorescent material mixed therein, to form a plurality of second fluorescent strips; and
fixing the plurality of first fluorescent strips and the plurality of second fluorescent strips into a transparent sealant to form the fluorescent structure, wherein a maximum distance between every two of the plurality of first fluorescent strips is less than one millimeter, and a maximum distance between every two of the plurality of second fluorescent strips is less than one millimeter.

19. The method of claim 18, wherein the step of fixing the plurality of first fluorescent strips and the plurality of second fluorescent strips comprises:
fixing the plurality of first fluorescent strips into a portion of the transparent sealant to form a first fluorescent layer;
fixing the plurality of second fluorescent strips into a portion of the transparent sealant to form a second fluorescent layer; and
stacking and combining the first fluorescent layer and the second fluorescent layer.

20. The method of claim 18, wherein the step of fixing the plurality of first fluorescent strips and the plurality of second fluorescent strips comprises:
stacking the plurality of first fluorescent strips and the plurality of second fluorescent strips;
providing the transparent sealant to cover the plurality of first fluorescent strips and the plurality of second fluorescent strips; and
solidifying the transparent sealant covering the plurality of first fluorescent strips and the plurality of second fluorescent strips.
